(19) United States
(12) Patent Application Publication
(10) Pub. No.: US 2023/0118148 A1
(43) Pub. Date: Apr. 20, 2023

(54) DIFFERENTIAL CAPACITIVE SENSING BASED WEAR DETECTION

(71) Applicant: AZOTEQ HOLDINGS LIMITED, Nicosia (CY)

(72) Inventors: Frederick Johannes BRUWER, Paarl (ZA); Daniel Barend RADEMEYER, Paarl (ZA)

(21) Appl. No.: 17/968,825

(22) Filed: Oct. 19, 2022

(30) Foreign Application Priority Data
Oct. 20, 2021 (ZA) 2021/08015

(51) Int. Cl. G01D 5/24

(52) U.S. Cl. CPC G01D 5/2405

(57) ABSTRACT

A wearable electronic device with one or more receiver electrodes and a plurality of transmitter electrodes, with differential mutual-capacitance measurements used to determine wear status of the device, is described. Mutual-capacitance between receiver and transmitter electrodes is increased to compensate for weak coupling between grounded structures of the device and a surrounding electrical earth. Due to the nature of differential measurements used, the device may maintain mutual-capacitance sensing sensitivity despite said increase. Differential output channels may be dynamically identified and selected to ensure accurate wear detection.

### CROSS-REFERENCE TO RELATED APPLICATION

The present application claims priority from South Africa application ZA 2021/08015, filed Oct. 20, 2021, contents of which is hereby incorporated by reference into this application.

### BACKGROUND OF THE INVENTION

Wearable electronic devices are increasingly adopted. Conservation of battery power is a continuous challenge for designers of these devices. Capacitive sensing is often used in wearables to detect user proximity and touch in order to determine when and in which manner a device is worn, allowing control of power-hungry functions to better conserve battery power. For instance, for smart watches and fitness trackers, capacitive sensing may be used to determine when the device is worn sufficiently close to the skin of the user to enable optical sensing of the user's pulse rate. If the wear status is incorrectly determined it may cause a number of unwanted effects. These may include incorrect pulse measurements, wastage of battery power by the optical unit while trying to obtain an acceptable pulse reading and emission of light from the optical unit beyond the immediate vicinity of the smart watch or fitness tracker, which could be irritating to the user or to people close by, etc.

Another challenge facing designers of wearable devices such as smart watches and fitness trackers that use capacitive sensing is the close proximity of grounded structures. This may significantly increase the difficulty of using capacitive sensing to accurately detect proximity distance, user touch and press events. For example, due to the close vicinity of grounded structures, the use of self- or surface-capacitance to sense user proximity, as is commonly used in the art, may not work well, given that electric fields may couple directly and strongly from electrodes to the grounded structure, with little emanation of fields into the space around the electrode. The close vicinity of grounded structures in wearables may also limit the use of mutual- or projected-capacitance electrodes in a similar manner, with transmitter electrodes typically coupling strongly to grounded structures, which may leave little charge to be transferred to receiver electrodes.

In the case of mutual-capacitance measurements, compensation and electrode design could possibly be used to negate the effect of said grounded structures, for example by an increase in mutual-capacitance between electrodes. However, this may lead to a situation where little information on proximity distance can be gleaned from measurements, with only a definite touch by the user, for example by the user's arm, which can be detected. This may be non-ideal in the case of smart watches and fitness trackers, as wristbands tend to move a fair amount about the user's arm, and may be fastened from loosely to tightly, dependent on user preference, which may lead to a requirement for accurate detection of proximity distance as well as touch to correctly determine wear state.

Small wearable electronic devices are inherently space constrained. This may also limit the size or area of conductive ground structures that can be realized in these devices. As is known in the art of mutual-capacitance sensing, increasing the amount of local ground available to a mutual-capacitance circuit for coupling via electrical earth to the user may increase the change in mutual-capacitance the user can cause, leading to improved sensing/detection. Given said space constraints in small wearables, such an increase in local ground is often not an option. An alternative may be to increase the amount of mutual-capacitance through correct design of electrode layout and parameters. Unfortunately, this may lead to a design which sacrifices proximity detection to allow improved touch detection.

Wearable devices that utilize capacitive sensing also need to compensate for changes in ambient temperature, which may be quite abrupt as a user moves from one environment to another. Traditionally, this has been done through the use of capacitive sensing baselines and/or long-term averages (LTA). However, this approach may have limitations. For example, while in a wear detected state, it may not be possible to form an LTA for baseline adjustment with measurement data from an electrode used for said wear detection. One may make use of a second electrode which is not exposed to the user and apply a specific factor or weight to adjust the baseline using measurement data from said second electrode. But this may come at the cost of additional processing overheads and power consumption and may not be completely fool proof.

The present invention addresses the above problems and may allow the wear state of devices such as fitness trackers and smart watches, amongst others, to be determined with higher accuracy and robustness than what is possible with prior art solutions, fulfilling an unmet need currently experienced in the wearables technology space.

### SUMMARY OF THE INVENTION

In an effort to clarify the disclosure of the present invention, the following summary is presented. This should not be construed as limiting to the claims of the invention as it is merely used to support clarity of disclosure. A large number of alternative embodiments may exist that fall within the spirit and scope of the present invention, as may be recognised by one skilled in the relevant arts. This summary is not intended to identify key or critical elements of the disclosed subject matter, nor is it intended to delineate the scope of the present invention or the claims. It is intended to present a number of concepts in a simplified form to assist with the overall disclosure of the present invention.

Herein, “or” is used to convey inclusive and not exclusive, unless expressly indicated otherwise or indicated otherwise by context. Therefore, herein, “A or B” may mean “A, B, or_both,” unless expressly indicated otherwise or indicated otherwise by context. In addition, “and” is used to convey both joint and several, unless expressly indicated otherwise or indicated otherwise by context. Therefore, “A and B” may mean

“A and B, jointly or severally,” unless expressly indicated otherwise or indicated otherwise by context.

The present invention teaches that differential mutual-capacitance measurements may be used in a wearable device, for example a smart watch, fitness tracker, earbuds, earphones, headphones, health-monitor devices or others, or in a mobile device such as a smart phone, to negate the close vicinity of grounded structures, and through a sufficient amount of mutual-capacitance may allow accurate determination of user proximity distance from the wearable or mobile device as well as detection of touch and press events. To clarify, a wearable device embodiment of the invention may, for example have a ground conductor between capacitive sensing electrodes and a battery of said device. Due to the use of differential mutual-capacitance measurements as taught by the current invention, said ground conductor, for example a ground plate, may be in close vicinity to the capacitive sensing electrodes used for said differential measurements without preventing accurate detection of user proximity, touch and press events. In other words, the ground conductor may be within a sensing range of said electrodes. The location of the ground plate, or other grounded structures, between said electrodes and the battery may allow the latter to move without adversely affecting said detection of user proximity, touch and press events, for example. This may assist to accurately determine wear status which may be used to control functionality of said wearable device accordingly, or to determine when a mobile device is placed against a user's ear, for example. The use of differential mutual-capacitance measurements for wear detection in electronic devices may allow mutual-capacitance between electrodes to be increased significantly without compromising on proximity detection. This provides a clear benefit in small battery-operated systems which, due to space constraints, may be limited in the amount of increase in local ground area to improve coupling to the user via electrical earth and thereby mutual-capacitance sensing/detection.

To clarify the above, the present invention teaches that the problem of limited coupling between local ground and electrical earth may be solved by increasing the capacitance between receiver electrodes and local ground, and possibly also the capacitance between transmitter electrodes and local ground. The negative effect of these increases in capacitive coupling between electrodes and local ground on mutual-capacitance sensing may be countered by an increase in the values of mutual-capacitance between receiver and transmitter electrodes. Due to the use of differential mutual-capacitance sensing, such increases in mutual-capacitance may be done without losing the ability to discern user proximity events from user touch or press events. The present invention further teaches that the one-or-other compensation or cancellation method and/or apparatus may be used before, during or after said differential mutual-capacitance sensing to negate any detrimental effects of the increase in mutual-capacitance on sensing resolution, stability, repeatability, or temperature response.

According to another exemplary embodiment of the present invention, a matrix of mutual-capacitance electrodes comprising a plurality of at least two transmitter electrodes and a single central receiver electrode, e.g., may be used with differentially driven measurements to determine wear status of a wearable electronic device, for example a smart watch, fitness tracker, earbuds, earphones, headphones, health-monitor devices or others, or to detect when a mobile device, for example a smart phone, is in close proximity to a user. The matrix may be used in a manner which allows detection of signal saturation or degradation on specific differentially driven channels and identification of differentially driven channels which allows accurate detection of wear status or mobile device status, wherein a differentially driven channel may comprise at least two transmitter electrodes and a single receiver electrode, or more receiver electrodes. Allocation of differentially driven channels to said matrix may be performed dynamically as the wearable device moves on the wearer, or said mobile device moves closer to or further from a user, to allow continuous accurate detection of wear state or mobile device position.

Such a matrix of mutual-capacitance electrodes embodying the present invention may also be realized in an opposing layout format, wherein transmitter electrodes driven with opposing phases during differential capacitive sensing may be located directly opposite each other on two sides of a substrate, for example on opposite sides of a printed circuit board (PCB). One or more receiver electrodes may be located on each side of said substrate. As a specific example, the present invention may be embodied in a matrix using a two-layer PCB, with a single receiver electrode located on both the top and bottom layer, and centrally to a plurality of transmitter electrodes, with each transmitter electrode on said top layer opposed by another transmitter electrode of equal dimensions on the bottom layer. During sensing, the transmitter electrodes of a specific opposing pair may be driven with different phases, for example they may be driven with signals differing one-hundred-and-eighty degrees in phase.

When using differentially driven capacitive measurements to determine wear state of a wearable electronic device, situations may arise where the various electrodes of a specific differentially driven channel is located at exactly the same distance from a user. Alternatively, electrode-to-user distances for the various electrodes in a differentially driven channel may differ, but the capacitive coupling areas for said electrodes may be such as to compensate for the difference in electrode-to-user distances. In either case the differential output signal may be zero or near zero. If the wearable device is located at a sufficient distance from said user to qualify as a non-wear case, the zero or near zero value of the differential output should not pose a problem. However, if the wearable device is sufficiently close to the user that the wear status should be set to worn, the zero or near zero differential output may cause erroneous state identification or operation. The present invention teaches that this problem may be solved by connecting a discrete, known value capacitor between one of the transmitter electrodes and the receiver electrode of a differentially driven capacitive channel. If the wearable device is sufficiently far away from the user to qualify as a non-wear case, connection of said discrete capacitor may cause a large change in differential output. On the other hand, if the wearable device is located in close proximity to the user, and therefore couples strongly with the user, connection of said discrete capacitor may not cause a significant change in differential output, dependent on the amount of said coupling and the value of the discrete capacitor. In this manner a wearable device may discern between a worn and non-worn case where differential output is zero or near zero. The discrete capacitor may be any off-chip or integrated capacitor of a value as required by design parameters. For example, it may be an on-chip calibration capacitor, or other capacitors integrated into a circuit used for capacitive sensing or other purposes.

In yet another exemplary embodiment of the present invention, two consecutive measurements may be performed to detect when a wearable electronic device, or another device, is touching or in close proximity to a user. A first measurement of the two measurements may be characterised by driving a first transmitter electrode high first during a first phase, with said first transmitter electrode being part of a plurality of transmitter electrodes used in a differentially driven channel. A second transmitter electrode of said plurality is held low during said first phase. This may be followed by a second phase of said first measurement where a second transmitter electrode of said plurality is driven high, while said first transmitter electrode is held low, and thereafter repeating the first and second phases until the end of the first measurement. A second consecutive measurement may be characterised by said second transmitter electrode being driven high first during a first phase of the second measurement and said first transmitter electrode held low, whereafter said first transmitter may be driven high during a second phase of the second measurement and said second transmitter electrode held low, followed by a repetition of the first and second phases until the end of the second measurement. According to the present invention, by comparing the output of the first measurement with that of the second measurement, a wearable device, for example a fitness tracker, smart watch, earbuds, earphones, headphones, health-monitor devices or others, or a mobile device such as a smart phone, may be able to detect a user touch and/or proximity event with high accuracy, which may be used to determine wear status or whether the mobile device is on- or off-ear, for example. Such an embodiment may also advantageously negate changes in capacitive sensing output due to temperature, or other environmental changes. This may allow capacitive sensing without the need to use a baseline or long-term average value against which to test possible events.

According to the present invention, by using embodiments as disclosed herein, a wearable electronic device, or another device, for example a smart watch, fitness tracker, earbuds, earphones, headphones, health-monitor devices or others, may obtain differential capacitive output signals with a positive or negative polarity for a specific user touch or proximity event, dependent on the sensing electrodes used in a matrix of mutual-capacitance sensing electrodes. This may be used to discern specific wear cases for the wearable electronic device, which may allow improved wearable functionality and performance.

In another embodiment of the present invention, a wearable electronic device may utilize the same electrode structures used for differentially driven capacitive sensing, or another dedicated conductive structure, to also perform inductive sensing. Said dedicated conductive structure may be a coil structure, as is known in the art. The inductive sensing results may be used in a number of ways by the wearable electronic device, for example by a smart watch, fitness tracker, earbuds, earphones, headphones, health-monitor devices or others. Or it may be used by a mobile electronic device, for example a smart phone. It may be used to detect the proximity of conductive surfaces, for example a metal table, which may be used by said wearable device during determination of wear status, as an example. Or it may be used to measure or monitor magnetic fields incident on said electrode structures or said dedicated conductive structure, wherein said measurement or monitoring results may be used to facilitate further functionality of the wearable electronic device. As another example, inductance measurements via said electrode structures or dedicated conductive structure may be used to detect user activation of a user interface element, for example, a push-button. The inductance measurements may be based on charge transfer methods and circuits. The same circuit may be used to perform the capacitive measurements and said inductance measurements. For example, said same circuit may use a single measurement circuit for both capacitive measurements and for inductance measurements. As a further, more detailed example, said single measurement circuit may be a charge transfer measurement circuit. Said same circuit may also comprise an integrated circuit, using one or more dies.

In another exemplary embodiment of the present invention, a wearable, or other, electronic device may perform both differentially driven capacitive sensing as well as another form of sensing to monitor another parameter, for example inductive sensing, using the same or different circuits and the same or different electrodes and/or conductive structures. Said device may utilize measured changes in said another parameter, for example measured changes in inductance, to determine when to perform differentially driven mutual-capacitance sensing for wear, or other, detection, wherein the differentially driven mutual-capacitance sensing may be performed with or without the use of a baseline or LTA. According to the present invention, this may reduce complexity during capacitive sensing. For example, a device may perform either self-inductance or mutual-inductance sensing using a charge-transfer based circuit and a coil-like structure or structures. Changes in measured inductance may need to cross a predetermined threshold or thresholds before said circuit may be used to perform differentially driven mutual-capacitance measurements with a plurality of electrodes, for example with a single receiver electrode and a plurality of transmitter electrodes, similar to that described elsewhere during the present disclosure. The differential capacitance sensing values thus obtained may then be used without a baseline or LTA to detect wear status of said device. As more specific examples, said changes in the another parameter, for example changes in measured inductance, may be caused by changes in a mechanical configuration of the one-or-other structure within said device due to a user interaction, input or another event. For instance, the change in said another parameter, for example changes in inductance, may be caused by a user pressing a push-button, or by a user unfolding a set of head-phones, or by a user removing a set of earbuds from a storage and/or charging case. The skilled reader will appreciate that a large number of applications may exist which embodies the directly preceding teachings.

The present invention further teaches that differentially driven capacitive sensing measurements as described herein may be used to determine, or to help determine, the angle between a wearable electronic device, for example a fitness tracker, smart watch, earbuds, earphones, headphones, health-monitor devices or others, or a mobile device such as a smart phone, and a body part of a user, for example his or her arm. Said differentially driven capacitive sensing measurements may be used with, for example, gyroscope or accelerometer measurements to accurately determine said angle. The determined angle may be used by circuitry in the wearable device, or by other remote circuitry in communication with the wearable device, to improve optical measurements of blood flow and blood oxygen levels, for example. Said improvement may be made through use of said angle to adjust or correct optical measurement values to compensate for errors introduced due to said angle, or to compensate for other errors.

The present invention may be embodied in a method for wear detection by a wearable electronic device comprising mutual-capacitance sensing circuitry as well as grounded structures that are located within a sensing range of mutual-capacitance sensing electrodes of said device, said electrodes comprising one or more receiver electrodes and a plurality of transmitter electrodes, and wherein the method comprises at least one of the following two groups of steps. Group A, comprising forming pairs of transmitter electrodes, and driving the two transmitter electrodes within a pair out of phase with each other; determining mutual capacitance values for combinations of said receiver electrode(s) and specific transmitter electrodes of said plurality of transmitter electrodes; subtraction of mutual capacitance values of specific ones of said combinations from each other to find a plurality of sensing channel output values; selection of one or more of said sensing channels output values and determination of a wear status of said device based on the selected values. Group B, comprising the step of increasing mutual capacitance between the receiver electrode(s) and specific transmitter electrodes to compensate for weak coupling between the grounded structures and a surrounding electrical earth.

The present invention teaches a wearable electronic device comprising mutual-capacitance sensing circuitry as well as grounded structures that are located within a sensing range of mutual-capacitance sensing electrodes of said device, wherein the electrodes comprise one or more receiver electrodes and a plurality of transmitter electrodes, wherein transmitter electrodes are paired in groups of two by the device to drive the transmitter electrodes within a pair out of phase with each other, wherein mutual capacitance values of combinations of the receiver electrode(s) and specific ones of the plurality of transmitter electrodes are measured by the device, with mutual capacitance values of specific ones of said combinations subtracted from each other by the device to determine a plurality of sensing channel output values, wherein one or more of said channel output values are selected and used by the device to determine a wear status of said wearable device.

An exemplary embodiment of the present invention may be found in a wearable electronic device with mutual-capacitance sensing circuitry and electrodes, said electrodes comprising one or more receiver electrodes and a plurality of transmitter electrodes, wherein the device pairs transmitter electrodes in groups of two to drive the transmitter electrodes with a pair out of phase with each other, wherein the device increases mutual capacitance of combinations of the receiver electrode(s) and specific ones of the plurality of transmitter electrodes to compensate for weak coupling between a surrounding electrical earth and grounded structures, said grounded structures located within a sensing range of the electrodes in said device, and wherein mutual capacitance values of said combinations are measured by the device, with mutual capacitance values of specific ones of said combinations subtracted from each other by the device to determine a plurality of sensing channel output values, wherein one or more of said channel output values are selected and used by the device to determine a wear status of said wearable device.

### BRIEF DESCRIPTION OF THE DRAWINGS

The invention is further described by way of examples with reference to the accompanying drawings in which:

FIG. 1A shows transmitter and receiver electrodes as used for a single differentially driven channel in an exemplary embodiment of the present invention.

FIG. 1B shows sectional views for two usage cases of the electrodes in FIG. 1A where the differential output signal is at or near zero.

FIG. 1C shows a sectional view of the electrodes in FIG. 1A tilted to one side and the resulting positive differential output signal.

FIG. 1D shows a sectional view of the electrodes in FIG. 1A tilted to the other side and the resulting negative differential output signal.

FIG. 2 shows an exemplary embodiment of the present invention which uses a matrix of mutual-capacitance electrodes to realize a plurality of differentially driven sensing channels to detect wear status of a wearable electronic device.

FIG. 3 shows an exemplary flowchart of a method which may be used to discern between a worn case and a not-worn case of a wearable electronic device where initial differential output for both cases is at or near zero.

FIG. 4 shows exemplary output signals for an embodiment of the present invention that utilizes two consecutive measurements to determine wear status.

FIG. 5 shows typical measured temperature response of the capacitive sensing output for a wearable electronic device which embodies the present invention.

FIG. 6 shows typical measured differential output signals for a wearable electronic device which embodies the present invention and utilizes more than one differentially driven channel.

FIG. 7 shows an exemplary mutual-capacitance electrode matrix layout for a wearable device embodying the present invention.

FIG. 8 shows an exemplary embodiment in the form of a fitness tracker which includes a mutual-capacitance electrode matrix for wear detect as well as a coil to detect other materials.

FIG. 9 shows a flowchart describing an exemplary method embodiment for wear detection in a device with limited capacitive coupling between earth and local ground.

FIG. 10 shows a flowchart for an exemplary method embodiment using both inductive and differentially driven capacitive sensing.

FIG. 11 depicts an exemplary differentially driven capacitive sensing embodiment where transmitter electrodes with different phases are located on opposite sides of a substrate.

### DETAILED DESCRIPTION OF EMBODIMENTS

To further clarify the disclosure of the present invention, the following descriptions relating to the appended drawings are presented. These should not be construed as limiting to the claims of the invention and are merely used to support clarity of disclosure. A large number of other equivalent embodiments may be possible that still fall within the spirit and scope of the present invention, as may be recognised by one skilled in the relevant arts.

Herein, “or” is used to convey inclusive and not exclusive, unless expressly indicated otherwise or indicated otherwise by context. Therefore, herein, “A or B” may mean “A, B, or both,” unless expressly indicated otherwise or indicated otherwise by context. In addition, “and” is used to convey both joint and several, unless expressly indicated otherwise or indicated otherwise by context. Therefore, “A and B” may mean “A and B, jointly or severally,” unless expressly indicated otherwise or indicated otherwise by context.

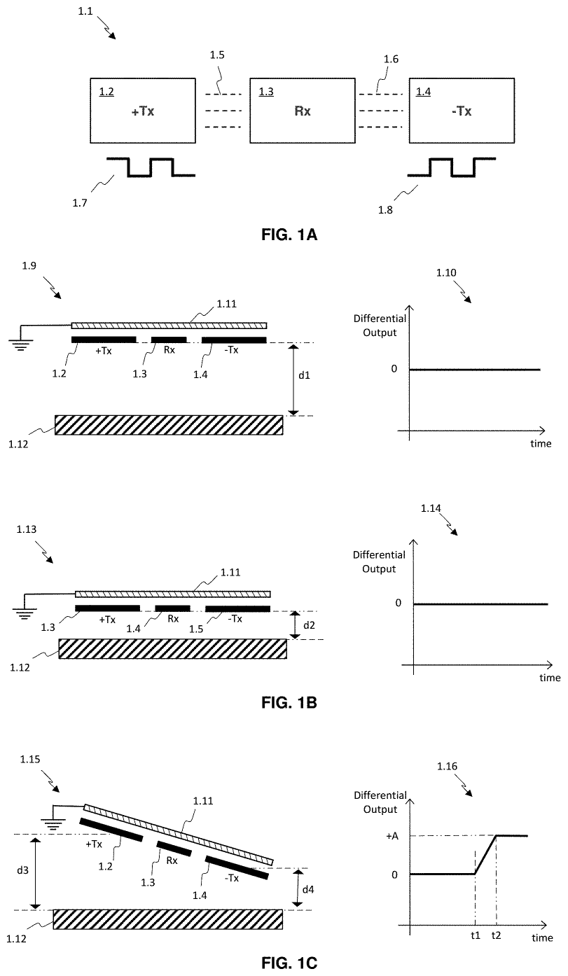

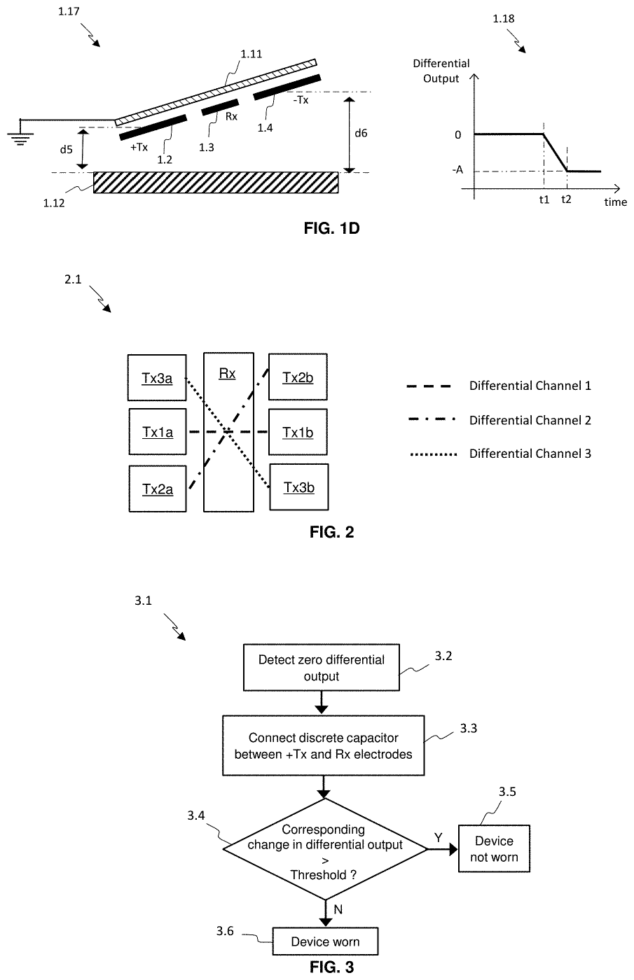

FIG. 1A depicts mutual-capacitance electrodes at 1.1 which may be used in an exemplary embodiment to realise a differentially driven capacitive sensing channel in a wearable electronic device. A first transmitter electrode 1.2 may be coupled to a receiver electrode 1.3 as shown symbolically by 1.5. A second transmitter electrode 1.4 may also be coupled to receiver electrode 1.3 as shown symbolically by 1.6. Transmitter electrode 1.2 may be driven by a pulse train as depicted qualitatively at 1.7, whereas transmitter electrode 1.3 may be simultaneously, or nearly simultaneously, driven by a pulse train as shown qualitatively at 1.8. The two pairs of electrodes, i.e. electrode pair 1.2 and 1.3 and electrode pair 1.4 and 1.3 may be used to form a single differentially driven capacitive sensing channel. A charge transfer method and circuits (not shown) may be used to measure the mutual-capacitance for each transmitter and receiver electrode pair, as an example. Measured mutual-capacitance of one pair, e.g., electrodes 1.4 and 1.3 may be subtracted by the wearable device, not shown, or another device or circuit, from the measured mutual- capacitance of the other pair, e.g., electrodes 1.2 and 1.3 to find the output of said differentially driven capacitive sensing channel, or vice versa. According to the present invention, the use of a differentially driven capacitive sensing channel for wear detection may allow said mutual-capacitance, or a value proportional to it, to be sufficiently increased to substantially negate the effect of grounded structures near the transmitter and receiver electrodes in the wearable device, while maintaining the ability to also sense user proximity with sufficient resolution and not just user touch. In other words, the effect of grounded structures located within a sensing range of said transmitter and receiver electrodes may be substantially negated. This is a clear improvement over prior art solutions where non-differential or single-ended mutual-capacitance measurements are used, and where an increase in the mutual-capacitance to negate the proximity of grounded structures in the wearable device comes at the cost of a reduction in the ability to sense proximity and/or proximity distance. It may also address the prior art problem of small-battery operated, non-differential mutual-capacitance systems that do not have the space to increase ground to improve coupling via earth to the user, but which also cannot increase mutual-capacitance for single-ended channels without compromising on proximity detection.

FIG. 1C and FIG. 1D illustrates sectional views of the embodiment from FIG. 1A used in an exemplary wearable application. As shown at 1.15, the two pairs of mutual-capacitance electrodes that form said differentially driven channel may be covered by a grounded structure 1.11 in a typical wearable device such as a fitness tracker, smart watch, earbuds, earphones, headphones, health-monitor devices or others. According to the present invention, if the mutual-capacitances between transmitter electrode 1.2 and receiver electrode 1.3 and between transmitter electrode 1.4 and receiver electrode 1.3 respectively are increased sufficiently, the effect of grounded structure 1.11 on capacitive sensing range and sensitivity may be largely negated. In the embodiment depicted at 1.15, a user 1.12 is closer to transmitter electrode 1.4 than to transmitter electrode 1.2, evident from depicted distances d4 and d3. This may cause the differential output to swing to a positive value as shown qualitatively at 1.16. To clarify, said differential output may be obtained, for example, by subtracting the mutual-capacitance value measured for transmitter electrode 1.4 and receiver electrode 1.3 from the mutual-capacitance value measured for transmitter electrode 1.2 and receiver electrode 1.3, or vice versa. For the scenario depicted in FIG. 1C, the measured mutual-capacitance for the electrode pair formed by 1.4 and 1.3 should be smaller than that measured for the electrode pair formed by 1.2 and 1.3, resulting in a positive differential output value as depicted after time t2. Up to time t1 both transmitter electrodes are equi-distant from user 1.12, which may result in a zero or near zero differential output as shown. Between times t1 and t2, transmitter electrode 1.4 moves closer to user 1.12, which may cause the increase in differential output depicted. After time t2, the wearable device is worn such that distances d3 and d4 are largely maintained, with the resultant constant differential output.

The embodiment shown at 1.17 in FIG. 1D is the inverse of that of FIG. 1C, as is evident from distances d5 and d6, and largely self-explanatory in the light of the above. For brevity's sake it will not be elaborated on further, except to note that the differential output swings negative in this case, as depicted at 1.18, with electrode pair 1.2 and 1.3 being closer to user 1.12 and resulting in a smaller mutual-capacitance than for electrode pair 1.4 and 1.3, as an example.

FIG. 2 depicts an exemplary matrix of mutual-capacitance electrodes at 2.1 which may be used in a wearable electronic device to dynamically realize differentially driven capacitive sensing channels for wear detection. Due to the nature of wearable electronic devices and their use, they may often shift position relative to a user. A differentially driven capacitive sensing channel may provide useful measurement data in one instant and in the next instant be unable to do so. For example, electrodes may suddenly move too far away from said user, due to user movement or objects engaging him or her, to provide useable capacitive sensing data. Or as another example, both transmitter electrodes of a differentially driven channel may suddenly move to a position with equal coupling to the receiver electrode, resulting in a zero differential output value. Or the electrodes may move to a position close enough to the skin of the user to effectively constitute short-circuits between each transmitter and receiver electrode pair at the capacitive sensing frequency used, which may lead to a zero or near zero differential output and increased insensitivity to any further decreases in distance between electrodes and the user. According to the present invention, an exemplary embodiment as shown in FIG. 2 may be used with a method and/or algorithm to dynamically assign and measure differentially driven capacitive sensing channels and compare and process values from these channels to accurately perform wear detection. In the embodiment shown, a single receiver electrode Rx is surrounded by six transmitter electrodes Tx1a, Tx1b, Tx2a, Tx2b, Tx3a and Tx3b. As illustrated, a wearable device (not shown) may, for example, dynamically form three differentially driven capacitive sensing channels during wear detection, with Channel 1 using electrodes Tx1a, Tx1b and Rx, Channel 2 using electrodes Tx2a, Tx2b and Rx and Channel 3 using electrodes Tx3a, Tx3b and Rx. The invention is not limited to the exemplary embodiment shown in FIG. 2 and may use any number or combinations of mutual-capacitance electrodes to dynamically form differentially driven capacitive sensing channels during wear detection. The associated method and/or algorithm used by the wearable device which embodies the present invention may use measured values of any number of differentially driven channels to determine which measured values should be discarded or ignored and which values may be processed further to determine wear state.

FIG. 1B illustrates two exemplary usage cases for the differentially driven capacitive sensing channel of FIG. 1A at 1.9 and 1.13 respectively, wherein the differential output is at zero or near zero. As shown at 1.9, transmitter electrodes 1.2 and 1.4 and receiver electrode 1.3 may be covered by a grounded structure 1.11. If said transmitter electrodes are both positioned at a distance d1 from a user 1.12, the capacitive coupling between each transmitter electrode and receiver electrode 1.3 may be substantially equal, which may result in a zero or near zero differential output, as shown at 1.10. Alternatively, transmitter electrodes 1.2 and 1.3 may be positioned at different distances from user 1.12 but coupling areas may be such that a zero or near zero differential output is obtained. In the embodiment at 1.9, the distance d1 represents a value larger than a threshold used to declare a worn state. In other words, the wearable device is too far away from user 1.12 at distance dl to constitute a worn state.

However, according to the present invention, the zero differential or near zero output shown at 1.10 should potentially not be used to declare a not-worn state, as a zero or near zero output may also be obtained when a wearable device is located in close proximity to a user 1.12 at a distance d2, as illustrated at 1.13 in FIG. 1B, with d2 less than a wear state threshold. Advantageously, the present invention teaches a solution to discern between the two cases illustrated at 1.9 and 1.13. FIG. 3 presents an exemplary flowchart of a method implementing this solution at 3.1.

The method shown at 3.1 starts by detecting that a differential output is zero or near zero, as shown at 3.2. This may be followed by the step of connecting a discrete capacitor between one of the transmitter electrodes and the receiver electrode of the differentially driven capacitive sensing channel under consideration, as shown at 3.3. Next, the step of checking for a corresponding change in the differential output, and whether it is larger than a predetermined threshold, may be performed, as shown at 3.4. If it is found that said corresponding change did occur, it may be deduced that the device is not worn, as shown at 3.5. However, if no corresponding change in differential output is detected, or a corresponding change is detected, but it is less than or equal to said predetermined threshold, it may be deduced that the device is worn, as shown at 3.6. This may be based on the premise that when the device is worn in close proximity to the user, coupling between each transmitter and receiver pair in the differentially driven channel may be quite high due to the low impedance path via the user's skin, or another surface. Therefore, connection of another discrete capacitor across one pair should have little effect. Naturally, this may be dependent on the design parameters at hand, with the capacitance of said discrete capacitor relative to the effective capacitance between each electrode pair which should be considered.

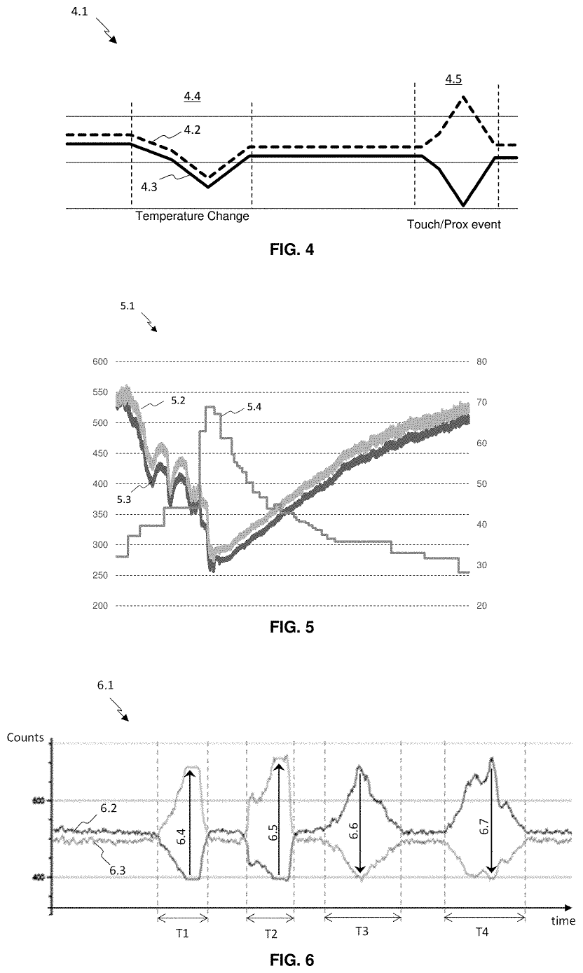

FIG. 4 presents at 4.1 exemplary, qualitative measurements as may be obtained for yet another embodiment of the present invention. The graphs 4.2 and 4.3 display differential channel output versus time for a first measurement and a consecutive second measurement in a differentially driven capacitive sensing channel. The first measurement 4.2 of the two measurements may be characterised by driving a first transmitter electrode of the differentially driven capacitive sensing channel high first during a first phase, while keeping a second transmitter electrode of the differential channel low. This may be followed by a second phase of said first measurement 4.2 where said second transmitter electrode is driven high while said first electrode is kept low, and thereafter repeating the first and second phases until the end of the first measurement 4.2. A second measurement 4.3 may be characterised by said second transmitter electrode being driven high first while said first transmitter electrode is kept low during a first phase of the second measurement 4.3, whereafter said first transmitter may be driven high while said second transmitter electrode is kept low during a second phase of the second measurement 4.3, followed by a repetition of the first and second phases until the end of the second measurement 4.3. According to the present invention, by comparing the output of first measurement 4.2 with that of the second measurement 4.3, a wearable device, for example a fitness tracker, smart watch, earbuds, earphones, headphones, health-monitor devices or others, may be able to detect a user touch and/or proximity event 4.5 with high accuracy, which may be used to determine wear status. In addition, the temperature response of both measurements 4.2 and 4.3 track each other due to the differential nature of the measurements, which may allow identification of a temperature change event as illustrated at 4.4.

In general, embodiments of the present invention may allow inherent compensation for temperature, or other environmental, changes. This is illustrated in exemplary manner by the typical charge transfer capacitive measurements shown at 5.1 in FIG. 5, with the left-hand vertical axis depicting charge transfer counts, as is known in the art, the right hand axis temperature and the horizontal axis time. Measurement 5.4 represents ambient temperature, while measurements 5.2 and 5.3 represents charge transfer counts for first and second transmitter and receiver electrode pairs that form a differentially driven capacitive sensing channel in a wearable electronic device, e.g. a fitness tracker smart watch, earbuds, earphones, headphones, health-monitor devices or others. It is evident from the depicted measurements that both pairs of transmitter and receiver electrodes respond in a similar manner to changes in temperature, with the differential output obtained by subtracting measurement 5.3 from measurement 5.2 being zero or near to zero over the whole temperature range depicted.

According to the present invention the use of differentially driven capacitive sensing measurements in a wearable electronic device, as described herein, may allow accurate capacitive sensing and wear detect without the use of a baseline or long term average to identify user touch and proximity events. For example, FIG. 6 presents at 6.1 charge transfer counts graphs 6.2 and 6.3 for a first transmitter and receiver electrode pair and a second transmitter and receiver electrode pair respectively, as used in a fitness tracker, smart watch, earbuds, earphones, headphones, health-monitor devices or others. During periods T1 and T2, user events, for example touch or proximity events, cause differential outputs with positive amplitudes 6.4 and 6.5. In a similar manner, during periods T3 and T4, user events, for example touch of proximity events, cause differential outputs with negative amplitudes 6.6 and 6.7, respectively. According to the present invention, it may be possible to accurately identify these events by merely looking at the differential output amplitudes and polarity, without using a baseline or long-term average threshold against which to test said events.

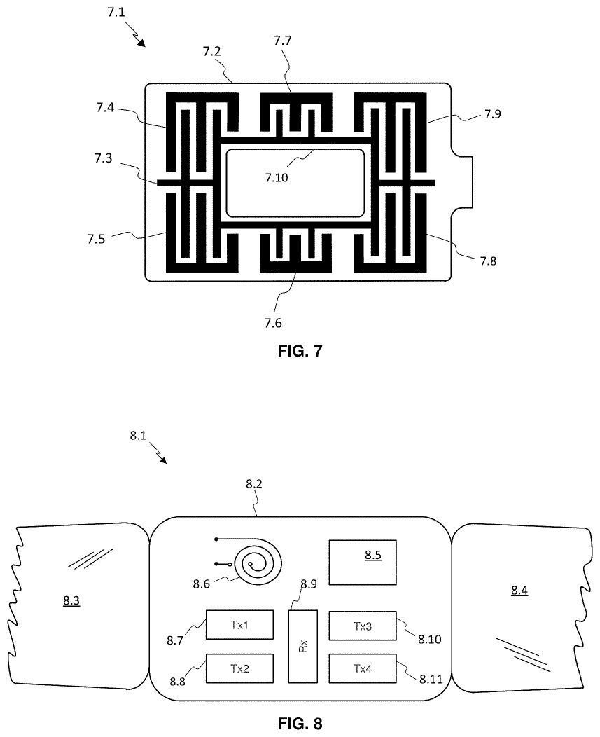

FIG. 7 presents an exemplary mutual-capacitance electrode layout for use in a fitness tracker, smart watch, earbuds, earphones, headphones, a health-monitor device or another electronic device, at 7.1. A printed circuit board 7.2 may have a central receiver electrode 7.3 deposited thereon, with said receiver electrode surrounding a central hole 7.10 in the printed circuit board. Hole 7.10 may be used, for example, to house other electronic components, for example an optical oximeter as is known in the art of fitness trackers. Receiver electrode 7.3 may have a comb-like structure to accommodate a plurality of transmitter electrodes 7.4 to 7.9, with said transmitter electrodes which may also have comb-like structures to mesh with the central receiver electrode, as illustrated. The transmitter and receiver electrodes may be connected to a circuit (not shown) to perform capacitive sensing measurements, for example charge transfer measurements. Said circuit may utilize the transmitter and receiver electrodes to form differentially driven capacitive sensing channels similar to that described herein. For example, it may form a first differentially driven channel out of electrodes 7.3, 7.6 and 7.7, a second differentially driven channel out of electrodes 7.3, 7.4 and 7.8 and a third differentially driven channel out of electrodes 7.3, 7.5 and 7.9. These channels may be used by said circuit, or another circuit (not shown), on their own or in any combination to detect when said fitness tracker is worn by a user.

Wearable electronic devices are often removed by the wearer and placed on the one or other surface, for example a conductive surface or a surface with appreciable conductivity due to moisture content or other properties. When only capacitive sensing is used for wear detect, such surfaces may result in an erroneous detection result. The present invention teaches that this may potentially be solved through the use of additional inductance measurements. FIG. 8 depicts an exemplary embodiment of this teaching at 8.1. A fitness tracker or smart watch 8.2 may comprise a matrix of mutual-capacitance electrodes 8.7 to 8.11 consisting of four transmitter electrodes 8.7, 8.8, 8.10 and 8.11 and a central receiver electrode 8.9, similar to that described hereinbefore. Two wristbands 8.3 and 8.4 may be used to strap said fitness tracker or smart watch 8.2 to an arm or other appendage of a user. Said fitness tracker or smart watch may also comprise a circuit 8.5, for example an integrated circuit, which may be used to perform differential capacitive measurements as taught by the current invention, or other capacitive sensing measurements. The capacitive measurements may be used by circuit 8.5 or by another circuit (not shown) to perform wear detection as taught earlier during the current disclosure. In addition, fitness tracker or smart watch 8.2 may also comprise a coil or inductor, or another inductive structure, 8.6, which may also be connected to circuit 8.5 in the one or other manner. According to the present invention, coil 8.6 may be used by circuit 8.5 or another circuit (not shown) to perform either self-inductance or mutual-inductance measurements as is known in the art. This may be used to detect proximity of inanimate, or other, surfaces, for example metal or conductive surfaces, in order to ensure said capacitive measurements do not provide erroneous wear detection results. It should be appreciated that the present invention may be practised without use of a dedicated coil or inductor for said inductance measurements. For example, electrodes 8.7 to 8.11 may be used for both capacitance measurements and inductance measurements.

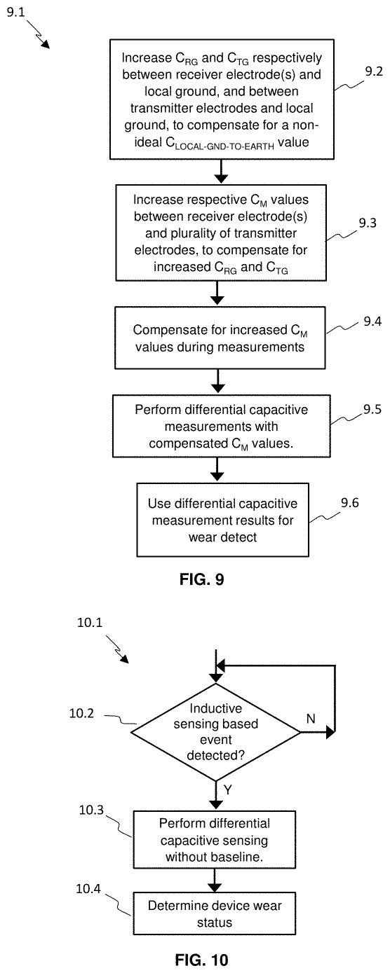

FIG. 9 presents an exemplary flowchart for a method which may embody the present invention, intended to provide a solution for the prior-art problem of not being able to easily detect proximity, touch and press events during wear detection in small battery-powered devices. As noted earlier, in such devices, the total area of local ground conductors may be limited, which may result in weak capacitive coupling between the local ground and electrical earth. Consequently, during conventional mutual-capacitance sensing, the current inventors have observed that it may be difficult to detect user proximity-, touch- and press-events, as may be required for wear detection. Typically, in such weakly-coupled-to-earth battery-operated devices, only user proximity- and press-events may be discerned using conventional mutual-capacitance measurements, without detection of an intermediate touch event, as may be required for wear detection. In other words, in such devices detection may transition rapidly from a proximity detection event to a press detection event, without detection of a touch event in between.

According to the present invention, a method as depicted in exemplary manner at 9.1 by FIG. 9 may allow accurate wear detection in small battery-powered devices using user proximity-, touch- and press-events. As a first step 9.2, the capacitive coupling between a receiver electrode or electrodes and the local ground is increased, along with the capacitive coupling between transmitter electrodes and the local ground. This step may be performed to counter the weak capacitive coupling between local ground and the surrounding electrical earth, typically due to limited ground conductor area in small, battery-operated devices.

As will be appreciated by those skilled in the art of capacitive sensing, step 9.2 may be detrimental to mutual-capacitance sensing sensitivity and/or resolution. Therefore, according to the present invention, step 9.3 may be performed, whereby mutual-capacitance values for each, or for some, of the receiver-transmitter electrode pairs may be increased to counter-act the effect of step 9.2 on sensing sensitivity and/or resolution. This may be followed by optional step 9.4 which may be used to compensate for the increased mutual-capacitance values during measurements. For example, step 9.4 may entail artificial subtraction of capacitance and/or charge values, or other values, during measurement and processing to compensate for said increases in mutual-capacitance. This may assist, as will be appreciated by skilled readers, to allow detection of small changes in measured capacitance.

Step 9.5 performs differentially driven capacitive sensing using mutual-capacitance values, similar to that described elsewhere in the current disclosure. Due to the use of differentially capacitive sensing, large mutual-capacitance values may be handled. In step 9.6 the results of said differential sensing are used for wear detect, similar to that described elsewhere in the current disclosure.

Sensing of another parameter, for example inductive sensing, may be used together with differential capacitive sensing to perform wear detection for an electronic device, according to the present invention. This may hold a number of advantages in terms of wear detection robustness, material detection and error rate. FIG. 10 presents an exemplary flowchart at 10.1 of a method where inductive sensing may be used in a gatekeeping manner for subsequent differential capacitive sensing. A continual check 10.2 may be performed to determine whether a predetermined inductive sensing event has occurred. Such an event need not be limited. For example, it may entail an inductive sensing value or change in values obtained when a pair of headphones are folded from closed to open. Or it may comprise an inductive sensing based pushbutton being pressed by a user. Or it may be a change in inductance measured when a wearable electronic device is fastened around an arm of a user, and so forth.

Once said inductive sensing event is detected, for example once a change in a measured self- or mutual-inductance value crosses a predetermined threshold, the method may perform differentially driven capacitive sensing similar to that described elsewhere in the current disclosure. For example, differential capacitive sensing without the use of a baseline or LTA value, as per step 10.3, may be performed. Subsequently or concurrently, the wear status of the electronic device may be determined, as per step 10.4, for example using the differential capacitive sensing value or values only, or using these along with values from said inductive sensing. It is to be appreciated that in the directly preceding description of FIG. 10, inductive sensing is purely used as an example of a parameter that can be sensed in addition to capacitive sensing, and that the present invention should not be limited in this regard. For example, the present invention may just as well be embodied by a wearable device where mechanical strain gauges are used to measure changes in resistance, and wherein said changes in resistance may be used in a gatekeeping function similar to that described for FIG. 10. Or the present invention may be practiced by an application where temperature is measured as said additional parameter, and used to determine when to perform differentially driven capacitive sensing for wear detection. The skilled reader will appreciate that a large variety of additional parameters exist which may thus be used in embodiments of the present invention.

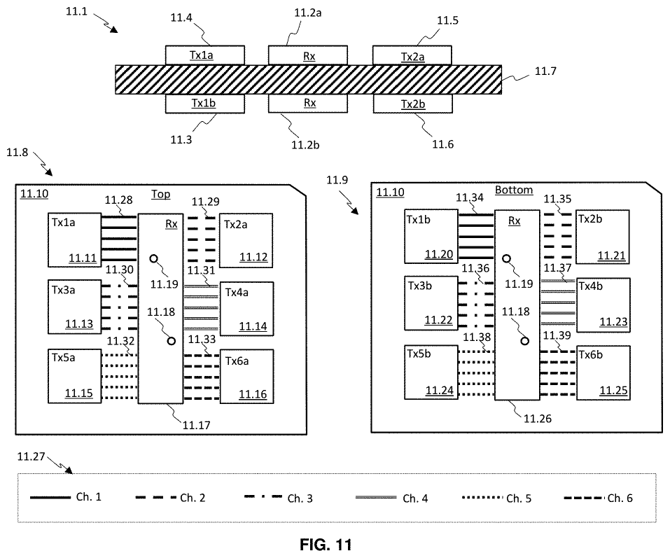

FIG. 11 presents exemplary electrode matrix embodiments of the present invention, characterised by the use of a double layer substrate, for example, a double layer PCB, with transmitter and receiver electrodes on both sides and wherein differentially driven capacitive sensing channels may be formed with transmitter electrodes located opposite each other. A cross-sectional view of a first exemplary embodiment is presented at 11.1, with a PCB 11.7 having a single receiver electrode (Rx) located on both its upper and lower surfaces, as shown by 11.2a and 11.2b. That is, the two electrodes 11.2a and 11.2b may form a singular receiver electrode, with the conductive material of said electrode on the upper and lower surfaces connected. A first differentially driven capacitive sensing channel may be formed with the receiver electrode Rx and transmitter electrode Tx1a at 11.4 on the top layer of PCB 11.7 in conjunction with transmitter electrode Tx1b at 11.3 on the bottom layer of PCB 11.7 directly opposite Tx1a. A second differentially driven capacitive sensing channel may be formed with the receiver electrode Rx and transmitter electrode Tx2a at 11.5 in conjunction with transmitter electrode Tx2b at 11.6 directly opposite Tx2a. In other words, for the embodiment shown at 11.1, two differentially driven capacitive sensing channels may be formed, the first comprising Rx with Tx1a and Tx1b and the second comprising Rx with Tx2a and Tx2b. In this manner, according to the present invention, differentially driven capacitive sensing channels may be formed using opposing transmitter electrodes. This may offer the advantage of a transmitter electrode(s) of a particular channel providing shielding to other transmitter electrodes of the channel. The transmitter electrodes of a channel may be driven in any manner described by the present disclosure, or any other manner. Differential channels also need not be formed in the manner described in the directly preceding, and may also comprise other configurations using receiver and transmitter electrodes.

A related six-channel differential capacitive sensing embodiment is depicted in exemplary manner at 11.8 and 11.9 in FIG. 11, with the top layer of PCB 11.10 shown at 11.8 and the bottom layer of PCB 11.10 (as would be seen when looking ‘through’ the PCB) at 11.9. Similar to before, the receiver electrode (Rx) comprises two conductive areas 11.17 and 11.26 located respectively on said top and bottom layer. These conductive areas may be connected together, for example they may be connected by via's 11.18 and 11.19. Symbol definition is presented at 11.27 and identifies the six exemplary differentially driven capacitive sensing channels. The lines at 11.28 to 11.39 is merely used in a symbolic manner to depict capacitive coupling between the respective transmitter and receiver electrodes, and should not be construed as limiting. The six channels will be described briefly. A first differential channel may be formed by using receiver electrode 11.17/11.26 with transmitter electrodes 11.11 on the top layer and 11.20 on the bottom layer. A second differential channel may be formed by using receiver electrode 11.17/11.26 with transmitter electrodes 11.12 on the top layer and 11.21 on the bottom layer. A third differential channel may be formed by using receiver electrode 11.17/11.26 with transmitter electrodes 11.13 on the top layer and 11.22 on the bottom layer. A fourth differential channel may be formed by using receiver electrode 11.17/11.26 with transmitter electrodes 11.14 on the top layer and 11.23 on the bottom layer. A fifth differential channel may be formed by using receiver electrode 11.17/11.26 with transmitter electrodes 11.15 on the top layer and 11.24 on the bottom later. A sixth differential channel may be formed by using receiver electrode 11.17/11.26 with transmitter electrodes 11.16 on the top layer and 11.25 on the bottom layer. For each of these six differential channels, the transmitter electrodes on the top and bottom layer of PCB 11.10 may be driven in any relevant manner described during the current disclosure. For example, the top and bottom transmitter electrodes of a particular differential channel may be driven with signals that are one-hundred-and-eighty degrees out of phase. Or they may be driven with another phase difference. The present invention is not limited in this regard. Further, the present invention need not be limited to the six differentially driven capacitive sensing channels depicted at 11.8 and 11.9 in FIG. 11, but may be embodied by alternate differential channel configurations as well.

1. A method for wear detection by a wearable electronic device comprising mutual-capacitance sensing circuitry as well as grounded structures that are located within a sensing range of mutual-capacitance sensing electrodes of said device, said electrodes comprising one or more receiver electrodes and a plurality of transmitter electrodes, and wherein the method comprises at least one of the following two groups (A, B) of steps:
A—forming pairs of transmitter electrodes, and driving the two transmitter electrodes with a pair out of phase with each other;
determining mutual capacitance values for combinations of said receiver electrode(s) and specific transmitter electrodes of said plurality of transmitter electrodes;
subtracting mutual capacitance values of specific ones of said combinations from each other to find a plurality of sensing channel output values; and
selecting one or more of said sensing channels output values and determine a wear status of said device based on the selected values;
B—increasing mutual capacitance between the receiver electrode(s) and specific transmitter electrodes to compensate for weak coupling between the grounded structures and a surrounding electrical earth.

2. The method of claim 1, wherein capacitive coupling between said transmitter electrodes and the grounded structures as well as capacitive coupling between said receiver electrode(s) and the grounded structures are increased to compensate for weak coupling between said grounded structures and a surrounding electrical earth.

3. The method of claim 1, wherein said device further comprises circuitry to measure changes in an additional parameter other than mutual-capacitance, and wherein the method includes a step of using the measured changes in the additional parameter to decide when to determine the wear status.

4. The method of claim 1, wherein said device is one of:
fitness tracker;
a smart watch;
a set of earbuds or earphones;
a set of headphones;
a health monitor device.

5. The method of claim 1, wherein said wear detection is performed without a baseline or long-term average value.

6. The method of claim 1, wherein said channel output values are dynamically selected.

7. A wearable electronic device comprising mutual-capacitance sensing circuitry as well as grounded structures that are located within a sensing range of mutual-capacitance sensing electrodes of said device, wherein the electrodes comprise one or more receiver electrodes and a plurality of transmitter electrodes, wherein transmitter electrodes are paired in groups of two by the device to drive the transmitter electrodes with a pair out of phase with each other, wherein mutual capacitance values of combinations of the receiver electrode(s) and specific ones of the plurality of transmitter electrodes are measured by the device, with mutual capacitance values of specific ones of said combinations subtracted from each other by the device to determine a plurality of sensing channel output values, wherein one or more of said channel output values are selected and used by the device to determine a wear status of said wearable device.

8. The device of claim 7, wherein capacitive coupling between said transmitter electrodes and the grounded structures as well as capacitive coupling between said receiver electrode(s) and the grounded structures are increased to compensate for weak coupling between said grounded structures and a surrounding electrical earth.

9. The device of claim 7 being one of:
fitness tracker;
a smart watch;
a set of earbuds or earphones;
a set of headphones;
a health monitor device.

10. The device of claim 7, wherein said device does not use a baseline or long-term average value to determine the wear status.

11. The device of claim 7, wherein said channel output values are dynamically selected.

12. The device of claim 7, wherein said device further comprises circuitry for connection of at least one discrete capacitor between a selected receiver electrode or electrodes and a transmitter electrode or electrodes to enable discerning of the wear status.

13. The device of claim 7, wherein said device further comprises circuitry to measure changes in an additional parameter other than mutual-capacitance, and wherein the device uses the measured changes in said additional parameter to decide when to determine the wear status.

14. A wearable electronic device with mutual-capacitance sensing circuitry and electrodes, said electrodes comprising one or more receiver electrodes and a plurality of transmitter electrodes, wherein the device pairs transmitter electrodes in groups of two to drive the transmitter electrodes with a pair out of phase with each other, wherein the device increases mutual capacitance of combinations of the receiver electrode(s) and specific ones of the plurality of transmitter electrodes to compensate for weak coupling between a surrounding electrical earth and grounded structures, said grounded structures located within a sensing range of the electrodes in said device, and wherein mutual capacitance values of said combinations are measured by the device, with mutual capacitance values of specific ones of said combinations subtracted from each other by the device to determine a plurality of sensing channel output values, wherein one or more of said channel output values are selected and used by the device to determine a wear status of said wearable device.

15. The device of claim 14, wherein capacitive coupling between said transmitter electrodes and the grounded structures as well as capacitive coupling between said receiver electrode(s) and the grounded structures are increased to compensate for weak coupling between said grounded structures and a surrounding electrical earth.

16. The device of claim 14 being one of:
fitness tracker;
a smart watch;
a set of earbuds or earphones;
a set of headphones;
a health monitor device.

17. The device of claim 14, wherein said device further comprises circuitry for connection of at least one discrete capacitor between a selected receiver electrode or electrodes and a transmitter electrode or electrodes to enable discerning of the wear status.

18. The device of claim 14, wherein said device does not use a baseline or long-term average value to determine the wear status.

19. The device of claim 14, wherein said channel output values are dynamically selected.

20. The device of claim 14, wherein said device further comprises circuitry to measure changes in an additional parameter other than mutual-capacitance, and wherein the device uses the measured changes in said additional parameter to decide when to determine the wear status.
